(19) United States
(12) Patent Application Publication
(10) Pub. No.: US 2002/0120565 A1
(43) Pub. Date: Aug. 29, 2002

(54) System and method for providing downloading services for digital objects

(76) Inventors: Philip Shi-Lung Yu, Chappaqua, NY (US); Stephen J. Boies, Mahopac, NY (US); Samuel Dinkin, Austin, TX (US); Paul Andrew Moskowitz, Yorktown Heights, NY (US)

Correspondence Address: MORGAN & FINNEGAN, L.L.P., 345 Park Avenue, New York, NY, 10154, US

(21) Appl. No.: 09/795,552

(22) Filed: Feb. 28, 2001

(51) Int. Cl. G06F 17/60; G06F 17/00; G01R 11/56; G01R 21/133

(52) U.S. Cl. 705/40; 705/412

(57) ABSTRACT

A program, is stored on a computer readable medium and has a module to calculate a usage value representing resource usage for an entity under a billing plan within a cycle, calculated from measurements of at least two measurable parameters and a module to bill for excess resource usage when an expected resource usage for the entity is less than the usage value for the entity within the cycle. A method of allocating resources involves receiving a value representing an estimate of a calculated expected resource usage under a billing plan within a cycle, derived from at least two measurable resource parameters, aggregating the value with a current actual resource usage for the cycle, and adjusting a resource allocation based upon a comparing of a result of the aggregating and a current available resource amount.

### FIELD OF THE INVENTION

This invention relates generally to provision of content over a network and more particularly to optimizing allocation of resources to fulfill those needs.

### BACKGROUND OF INVENTION

The Internet, or World Wide Web, has made it possible for individuals with computers to access content not previously available to them in a convenient manner. In general, users access content is provided by a content source according to the functional arrangement shown in FIG. 1. A user 100 accesses a web site hosted by a provider 120 in order to view and/or download content provided by a content source 140.

Unfortunately, access to a web site may become slow or even disabled when too many users attempt to access the web site concurrently. This is because the provider may have limited resources available in order to satisfy the demands of all users at the same time. In order to alleviate the problem, arrangements such as shown in FIG. 2 have been used. In the arrangement of FIG. 2 the user and content source are functionally the same, however the provider incorporates multiple assets that can be utilized if demand becomes too heavy. Depending upon the case, those additional resources may take the form of a mirror site which is an additional web site having identical content to the primary site. Alternatively, the provider may have additional servers that they can bring online to handle increased demand. In either case, a resource manager 220 may be employed such that if demand exceeds some specified amount, either additional traffic will be rerouted to the mirror site or the additional resources will be brought online.

All the aforementioned arrangements of FIG. 2 suffer from the same drawback in that they require a provider to have, at the ready, resources they may never use, or face the risk that a spike in demand may cause the same problems as discussed in connection with FIG. 1. Thus, there remains in need in the art for an improved way of managing resources of an internet provider.

### SUMMARY OF THE INVENTION

In general, a first aspect of the invention is a method of providing resources. The method involves receiving a value representing an estimate of a calculated expected resource usage under a billing plan within a cycle. The value having been derived from at least two measurable resource parameters and the billing plan including a charge of a base amount when an actual calculated resource usage during the cycle does not exceed the calculated expected resource usage and a surcharge when the actual calculated resource usage during the cycle exceeds the calculated expected resource usage. The method further involves measuring, during a period, at least two parametric resource values representative of resource usage, calculating a current actual resource usage value based upon a result of the measuring, determining if the estimate has been exceeded within the cycle by comparing the current actual resource usage value with the value, and billing according to the plan based upon a result of the determining.

In general, a second aspect of the invention is a method of allocating resources. The method involves receiving a value representing an estimate of a calculated expected resource usage under a billing plan within a cycle, the value being derived from at least two measurable resource parameters, aggregating the value with a current actual resource usage for the cycle, and adjusting a resource allocation based upon a comparing of a result of the aggregating and a current available resource amount.

In general, a third aspect of the invention is a system. The system has a central processor unit configured to determine if an aggregate of a system actual resource usage and a value, calculated from at least two measurable resource parameters and representing an estimate of a calculated expected resource usage under a billing plan within a cycle, will exceed an available resource capacity. The system also has a database containing data, at least some of the data collectively representing the system actual resource usage, at a point in time.

In general, a fourth aspect of the invention is a program, stored on a computer readable medium. The program has a module to calculate a usage value representing resource usage for an entity under a billing plan within a cycle, calculated from measurements of at least two measurable parameters, and a module to bill for excess resource usage when an expected resource usage for the entity is less than the usage value for the entity within the cycle.

Still other aspects involve numerous additional features and provide further advantages as set forth, and beyond those set forth, herein. The enumerated advantages and features described herein being a few of the many advantages and features available from representative embodiments. These enumerated advantages and/or features are presented only to assist in understanding the invention. It should be understood that they are not to be considered limitations on the invention as defined by the claims, or limitations on equivalents to the claims. For instance, some of these advantages are mutually contradictory, in that they cannot be simultaneously present in a single embodiment. Similarly, some advantages are applicable to one aspect of the invention, and inapplicable to others. Thus, the specifically referred to features and advantages should not be considered dispositive in determining equivalence. Additional features and advantages of the invention will become apparent in the following description, from the drawings, and from the claims.

### BRIEF DESCRIPTION OF THE DRAWINGS

A better understanding of the present invention will be had upon reference to the following detailed description, when read in conjunction with the accompanying drawings, in which:

FIG. 1 is an example of a prior art system for providing content to users;

FIG. 2 is a second example system for providing content to users according to the prior art;

FIG. 3 illustrates an example of the functional components of a system in accordance with the present invention;

FIG. 4 illustrates an example computer suitable for use in accordance with the invention;

FIG. 5 is an example flowchart for a process operating in accordance with the present invention;

FIG. 6 is an example flowchart for a simplified billing procedure according to the present invention; and

FIG. 7 is one example of a portion of a simplified database according to the present invention.

### DETAILED DESCRIPTION OF THE INVENTION

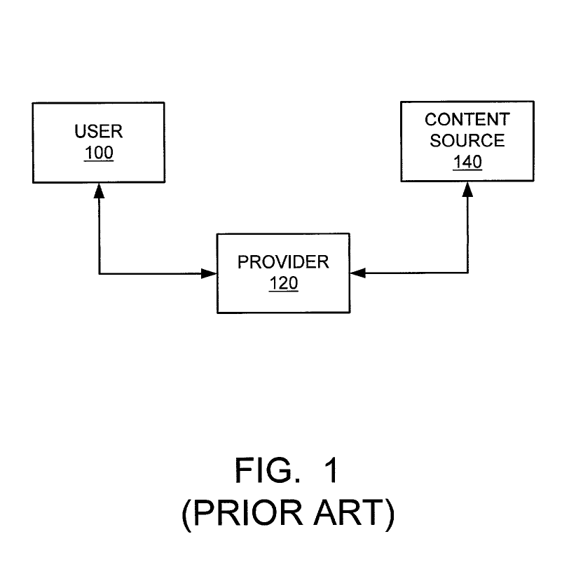

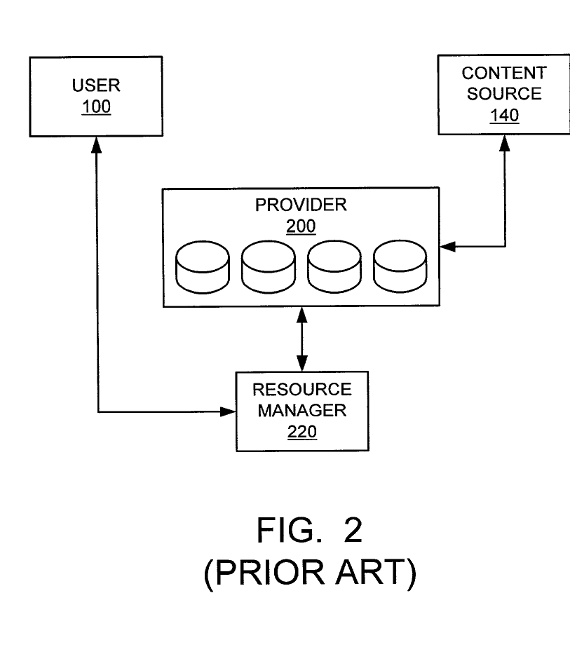

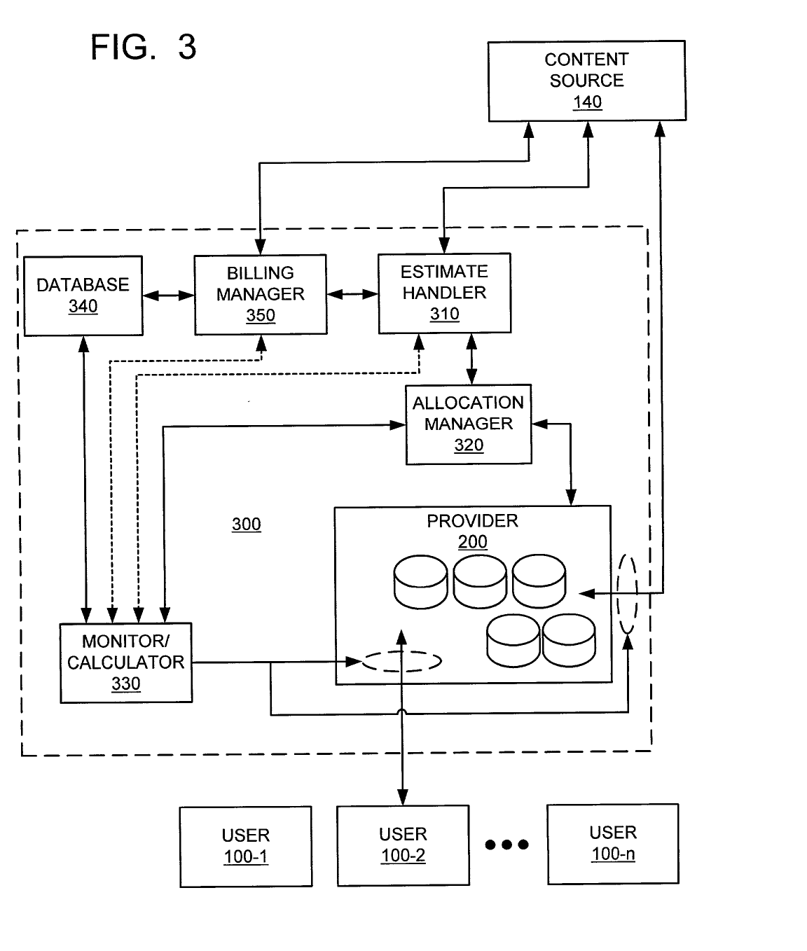

FIG. 3 shows the functional components of an example system according to the present invention. The users 100-1, 100-2, through 100-n are each, for all intents and purposes, considered functionally the same as the user 100 discussed in connection with FIGS. 1 and 2. It is presumed, for purposes of illustration, that neither the users nor the content source 140 are functionally part of the invention, although in some variants the content source 140 may be part of the system 300 and hence, nevertheless, part of the present invention from an implementation standpoint. Since measurement of parameters such as, for example, amount of storage, bandwidth, processor utilization, website “hits”, number of files, pages, etc. are individually well known and can be accomplished in numerous ways and such implementation details are unimportant to an understanding of the invention, to avoid introducing unnecessary complexity such details have been omitted.

The system 300 incorporates a number of functional components. A provider 200 similar in function and operation to the provider of FIG. 2, an estimate handler 310, an allocation manager 320, a monitor/calculator 330, a database 340 and a billing manager 350.

The provider 200 receives content from the content source 140 and makes it available to a user accessing a web site hosted by the provider 200. The estimate handler 310 receives estimates from multiple content sources (only one of which content source 140 is shown), as will be described in greater detail below, regarding their expected peak usage per specified measurement cycle and/or aggregate (or accumulated peak) usage per billing cycle. The allocation manager 320 allocates provider resources based upon both estimated and actual usage information. The monitor/calculator 330 continuously or cyclically monitors various parameters to determine resource usage, and calculates parametric based information based upon the monitoring. A database 340 is used to hold the results of the monitoring and/or calculated values to facilitate proper billing and, in some implementations, assist with allocation or re-allocation of resources. The billing manager 350 handles billing for one or both of peak resource usage during measurement cycles and/or aggregate or accumulated usage during the billing cycle, based upon both estimated and actual resource usage relative to each pertinent content source 140.

These functional elements interact with each other as follows: the estimate handler 310 receives an estimate of expected peak resource usage from the content source 140. The estimate is based upon a relationship between two or more measurable parameters obtained from the activities of the content source 140 and/or a user. Presently, to the extent any form of estimating may be done, for example, in connection with the system of FIG. 2, such estimates are typically based upon a particular single parameter such as: an amount of storage, a number of “hits” or a bandwidth requirement, which may fluctuate wildly with time such that it may be difficult, if not impossible, for a provider 200 to dynamically manage resources and plan for future needs in an efficient manner. Advantageously, by measuring multiple parameters and utilizing calculated values derived from two or more of those parameters, estimates which will be relatively constant within a specified period can be identified. Thus, for example, estimates based upon bandwidth per unit of storage, hits per file or page, processor utilization per number of files, bandwidth per hit, or some other calculable combination of two or more parameters can be examined to find the combination that remains relatively constant per cycle. This can allow for more accurate management of resources to meet aggregate peak usage demands during a particular cycle.

Once it receives the estimate, the estimate handler 310 provides that information to the billing manager 350, for purposes of billing, and the allocation manager 320, for purposes of allocating resources.

The allocation manager 320 receives the estimate information and utilizes it along with actual usage information received from the monitor/calculator 330 to more efficiently allocate the providers resources to accommodate user demands. The allocation manager 320 can be configured, in one variant, to adjust or shift the allocation of the provider's available resources according to both actual and estimated resource needs to avoid overtaxing or under-utilizating the provider's resources (i.e. to optimize resources by more closely matching resources to peak demand). In another variant, the allocation manager 320 also brings resources on or off line as required or diverts traffic to particular resources to balance loading.

The monitor/calculator 330 is responsible for measuring usage of the provider resources on a continuous or periodic basis. In the case of periodic measurements, such measurements occur during a measurement cycle which may or may not coincide with a billing cycle, although typically there will be at least several measurement cycles per billing cycle. The monitor calculator also converts those measured parametric values to calculated values for purposes of comparison with values reflective of the estimates contained within the system. In this manner, actual calculated parametric usage of a provider's resources may be ascertained relative to the estimated calculated values. In operation, the monitor/calculator 330 provides utilization information to the allocation manager 320 to allow it to effectively allocate or optimize resource allocation. The monitor calculator 330 also stores the measured information in a database 340 for purposes of accumulating measured information during a cycle for a particular content source and/or billing.

The billing manager 350 is responsible for all billing functions associated with the provision of the content source's content. The billing manager 350 receives the content source estimate via the estimate handler 310 and stores that estimate in the database 340 for the particular content source 140. The billing manager 350 also, at the end of a billing cycle, compares the calculated actual utilization information with the calculated estimated utilization information in the database 340 to ascertain the appropriate billing procedure to invoke, typically based upon a billing plan established for the content source 140. Depending upon the particular implementation, the billing manager 350 may also functionally communicate with the monitor/calculator 330, for example, in cases where billing is done continuously by deducting from funds in an existing account, such that the billing manager may need to know that a content source's estimate has been exceeded at or about the time it happens.

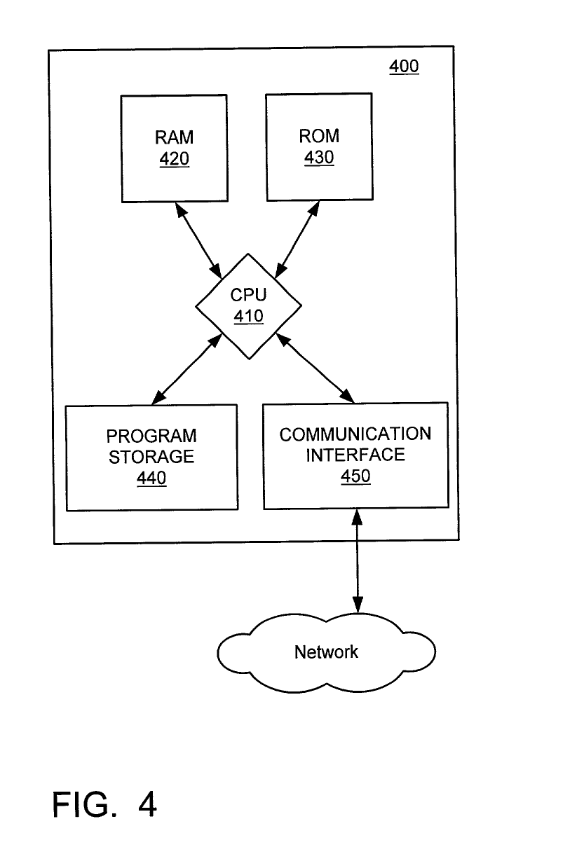

FIG. 4 is a simplified block diagram of the hardware elements of a computer 400 suitable for implementation of one or more of the functional blocks of FIG. 3. As shown, the computer 400 is made up of CPU 410 of suitable speed and processing power to accomplish the functions as described herein. The CPU 410 is connected to RAM 420 and ROM 430 to facilitate execution of a program obtained from program storage 440 or for processing data received via communication interface 450. The program storage 440 contains the program modules that implement the functionality of one or more of the particular functional system elements. The communication interface 450 allows the computer 400 to communicate, for example, with the user 100, the content source 140, and/or other computers if they are implementing functions of one or more of the provider 200, estimate handler 310, allocation manager 320, monitor/calculator 330, database 340 and/or billing manager 350 that are not implemented by that computer 400. Depending upon the particular functional element or elements it implements, the computer 400 may be a basic computer such as an IBM personal computer, a single or multi-processor web server, a main frame computer or even a highly parallel computer.

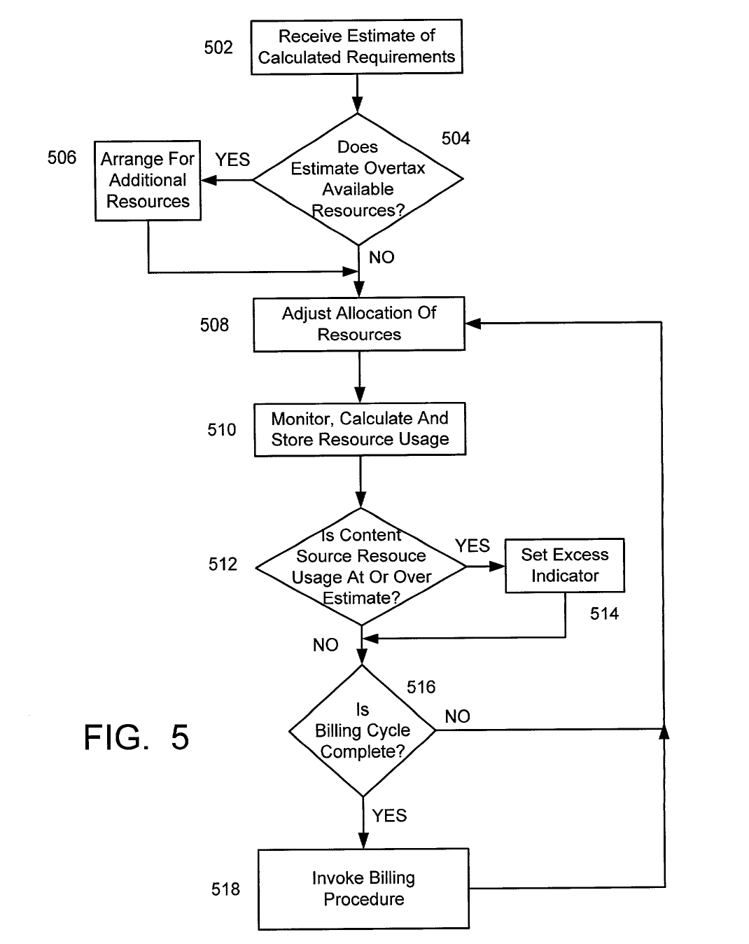

FIG. 5 is a flow chart of an example flow for the system of FIG. 3. In accordance with the flow chart, the system receives an estimate of the peak and/or aggregate or accumulated calculated requirements the content provider expects to be needed for a given cycle or from cycle to cycle (502). Depending upon the particular case, the cycles may be measurement cycles or billing cycles. The system takes that estimate and compares it with the available resources to ascertain whether the estimate, when added to the current system's state as projected, will cause an overtaxing of the available resource peak (504). If so, the system can arrange for any additional needed resources to satisfy the projected demand peak (506). Once additional resources are arranged for, or if no additional resources are necessary, the system adjusts the allocation of its present resources in view of the estimate (508). The system then monitors resource usage, by taking measurements on a continual or semi-continual basis, calculates parametric information from measurements of two or more parameters for each content source whose content is being accessed and stores the monitored and calculated values in the database as described herein (510). The system also checks on a continual basis whether the resource usage for a particular content source is at or exceeds the estimated amount or limit (512). Depending upon the particular implementation if the estimate is or has been exceeded, an excess indicator is set (514) which may involve merely setting a flag in the database for the particular content source and/or sending a notification to the billing manager 350. The system then checks to see whether, for the particular content source, the billing cycle is complete (516) if so, the appropriate billing procedure is invoked (518) and the system returns to its allocation procedure (508). Alternatively, if the billing cycle is not complete, the system merely returns to the allocation procedure (508).

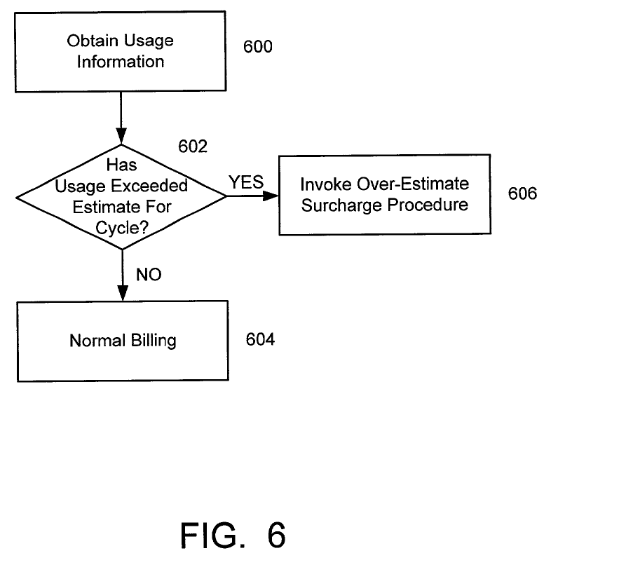

FIG. 6 is a flowchart of a highly simplified billing procedure such as would be invoked in step 518 of FIG. 5. In accordance with that procedure, the billing manager 350 in the system will obtain the usage information from the database 340 and, if the usage has not exceeded the estimate for the cycle (602) the normal or basic billing procedures (604) will be invoked. Alternatively, if the usage has exceeded the estimate for the cycle (602) an over estimate or surcharge procedure (606) will be invoked.

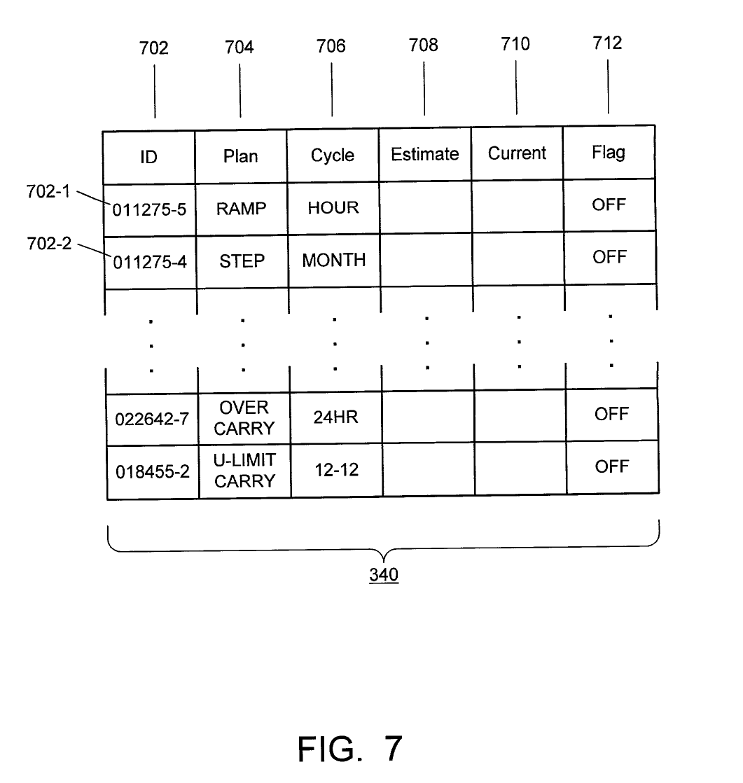

FIG. 7 is one example of a portion of a simplified database 340 according to the invention. As shown, the database 340 includes at least four customer entries (represented by an account identifier “ID”) 702. Notably, two of the entries 702-1, 702-2 are for different accounts for the same content source 140. Thus, to the extent a single content source 140 can segment their needs and provide separate estimates thereof, an advantage flowing from certain variants is that, their needs can be managed and billed on a per segment basis.

In the simplified database portion of FIG. 7, each entry has an associated plan identifier 704, a cycle identifier 706, a field for the estimate 708, a field for the current usage 710, and a flag field 712.

The plan identifier 704 field identifies the type of billing plan a customer has contracted for. As shown in FIG. 7, there are at least four different types of plans available: “Ramp”, “Step”, “Over Carry” and “U-Limit Carry.” In the example, a “Ramp” plan is one where, once the estimate amount is reached, a surcharge applies for each additional calculation unit of resource used. Thus, with this plan, the estimate serves as a threshold value and, once surpassed, the surcharge is based upon actual usage thereafter. A “Step” plan is similar to a Ramp plan, in terms of the estimate serving as the initial threshold however, once the threshold is surpassed, a higher fixed rate is invoked for the excess. Depending upon the particular case, there may be a single step or several steps, which involve successive threshold levels and commensurate successively higher surcharges for usage above the estimate. The “Over Carry” plan allows the unused difference between the estimate and actual resource usage in one cycle (or some portion thereof) to be applied to the next cycle. The “U-Limit Carry” plan allows (some or all) resource usage in excess of the limit to, for billing purposes, be subtracted from the estimate amount in the following cycle. Stated another way, the “U-Limit Carry” plan allows one to “borrow” usage from a subsequent cycle for billing purposes. of course, depending upon the particular implementation, one or more of these plans may not be available or other plans, for example, exponentially increasing surcharges may be substituted or used, or complex combinations thereof may be employed, the particular plan being only limited by the ability of the system to measure and calculate resource usage and/or the creativity of one or more of the entities involved.

The cycle 706 field identifies the period to which the estimate applies which may, or may not, coincide with a billing cycle. As shown, a cycle can be, for example, an hour, month or day, expressed in those units or sub-units such as seconds or milliseconds. Additionally, a cycle can have multiple components. For example, as shown in FIG. 7, one of the cycles is indicated as “12-12”. What this means is that a cycle is 24 hours broken up into two 12 hour components reflecting a significant disparity between resource requirements in the first and second halves of the 24 hour period, the first being a high estimate, the second a low estimate. Thus, for this plan, the “U-Limit Carry” allows the borrowing of resources from the low usage component if the high usage estimate is exceeded.

The estimate 708 field is used to store the estimate received from the estimate handler 310.

The current 710 field is used to store the current value (calculated from the two or more measured parameters) at any point in time as an accumulation of values during the cycle. Thus, by comparing the value in this field with the corresponding entry in the estimate field 708 for the account, it can be determined whether the estimate has been exceeded for that entity or account.

The flag 712 field is used to signal that the estimate value for the entity or account has been exceeded. Typically, the flag is used to specifically identify that an estimate has been exceeded to the billing manager 350.

A further advantage to some embodiments is that the estimate may also be updated based upon the usage tracking. Thus, in some variants, more complex databases are used and include additional fields for tracking average, peaks and/or changes in resource usage between two successive cycles or on a running basis. This allows for a fine tuning of an estimate over time. Moreover, by updating the estimate, the allocation can be changed to more accurately reflect future needs. Thus, in some implementations, the billing manager 350 can pass updated estimate values to the estimate handler 310 for provision to, and use by, the allocation manager 320, and in other implementations, the billing manager 350 can pass the updated estimate directly to the allocation manager 320 if the two are communicatively coupled to each other

Having shown and described the various functional elements of a system employing the principles of the invention, the operation of the system will be described by way of a representative example which illustrates a few of the numerous variants consistent with the principles of the invention.

In this example, for simplicity we presume an arrangement configured according to FIG. 3, where all of the functionality is part of a single system 300, although set forth above, the various functions could be indistinguishably consolidated together in one system, implemented in some combination of separate systems in communication with each other, or combined in some manner with the content source 140.

In the example, presume that a content source 140 is the type of entity that provides timely content related to the events of the day on an immediate and ongoing basis. The content source 140 is incapable of directly estimating their requirements (in terms of bandwidth, storage, processor utilization, hit count, etc.) during any given time period as a relatively static need with any reasonable accuracy. By reviewing usage reports from their prior resource manager 220 they have, however, empirically recognized that whenever a breaking event occurs, the demand in terms of bandwidth tracks the amount of storage they require for additional related content except, the storage needs lag the bandwidth needs by, on average, one half hour.

As a result, the content source 140 enters into an arrangement with the operator of the system 300. The content source 140 provides an estimate based upon their empirical analysis that they will require a continuing 140 Megabits/sec of bandwidth for every megabyte of storage. The arrangement provides for a “ramped” plan whereby, for a fixed rate per hour, the system 300 will continuously have available 145 Megabits/sec of bandwidth for every megabyte of storage. Should the content source 140 exceed that amount, a surcharge of a specified price will be applied for every megabit/sec per megabyte thereafter within the hour.

At or prior to the time when the content source 140 is to begin providing its content, for access via the provider 200, the estimate of 145 Megabits/sec of bandwidth per megabyte of storage is provided by the estimate handler 310 functional unit to the allocation manager 320 function so that it can determine if there are sufficient provider 200 resources to satisfy the expected demand. If so, as in this example, the allocation manager 320 need not engage, or trigger engagement of any additional resources. If not, depending upon the particular implementation, the allocation manager 320 informs the provider 200 that additional resources are required, so that the provider 200 can bring them on line or causes additional resources to be made available to accommodate the new demands. The estimate handler 310 also informs the billing manager 350 of the estimate for billing purposes.

The billing manager 350 stores the estimate in a field of the database 340 associated with the content source 140 for later usage.

The content source 140 provisions its content to the provider 200, where it is stored for access, in this example, by a user 100.

As activity involving the provider 200 occurs, i.e. between provider 200 and user 100 or provider 200 and content source 140, the monitor/calculator 330 monitors that activity, where calculation of values are required it performs the calculations, and it updates the database 340 as necessary. In the present example, assume for simplicity that a cycle for the content provider 140 is 24 hours and, as necessary, content is provisioned by the content source 140 that is accessed by a group of users 100-1, 100-2, etc . . . As the content provider 140 provisions its content during the cycle, the monitor/calculator 330 measures that activity and updates the database 340 to reflect any change in storage resources used. Similarly, as users access the content, the monitor/calculator 330 measures user activity in terms of bandwidth per second and calculates a bandwidth per second per megabyte of storage value relative to that usage which is used to update the current value in the database 340 for the content provider 140 at appropriate intervals.

From this point in the example, several different scenarios can occur.

In one scenario, at some point, the monitoring indicates that the resources needed by the provider 200 may be inadequate if some level of further net resource demand is required. In this scenario, the monitor/calculator 330 signals the allocation manager 320 in such a manner as to inform it that additional resources are needed. The allocation manager 320 then brings additional resources on line or arranges for additional resources to satisfy the needs.

In a second scenario, the provider 200 has ample resources during the cycle. At the end of a cycle, the billing manager 350 accesses the database 340 and, if a flag 712 is available, checks the flag 712 to see whether the estimate has been exceeded during the cycle. If either the flag 712 indicates that the estimate has not been exceeded or, where a flag is not available, the current value 710 is less than the estimate, the billing manager 350 resets the current value 710 and bills in accordance with the particular plan. Additionally, to the extent the particular plan provides for an adjustment to estimate or a credit of unused estimate to the next cycle, the billing manager 350 makes the appropriate adjustment. Alternatively, in some implementations, i.e. where the billing manager 350 adjusts the estimate values in the database 340, the change in estimate value is also passed to the estimate handler 310 function, so that that change in the estimate can be accounted for by the allocation manager 320.

Advantageously, since the monitor/calculator 330 is regularly accessing the database 350 and communicating with the allocation manager 320, any change for the next cycle affecting resource management and/or calculations can be taken into account, if desired, at or near the time it occurs.

In the third scenario, the provider 200 again has ample resources during the cycle. In this scenario, presume that at some point during the cycle, the estimate is exceeded. As a result, if a flag 710 is available, the flag 710 is set by the monitor/calculator 330, when the update of the current value indicates that the estimate has been exceeded.

At the end of a cycle, the billing manager 350 accesses the database 340 and, if a flag 710 is available, checks the flag 710 to see whether the estimate has been exceeded during the cycle. If no flag was available, the billing manager 350 will directly compare the current value 710 to the estimate value 708 to determine if the estimate has been exceeded. Since, in this scenario, a flag 710 is available and the flag 710 has been set to indicate that the estimate has been exceeded, the billing manager 350 sets the values according to the particular plan (i.e. to set the current value to zero or to reflect any borrowing, or to change the estimate value). Based upon the excess and the plan, the billing manager 350 bills the content source for the base amount and adds a surcharge based upon the excess and the terms of the particular plan.

Other Variants

Having described the invention in a simplified manner for purposes of understanding, it will be recognized that numerous more complex and/or commercially suitable arrangements are possible.

For example, since the above description presumes that content sources can supply material to the provider 200 at any time, in some implementations, it may actually be desirable to limit or stagger the times that content sources can provide their material to a provider 200. This is because, otherwise, there is no way to reliably predict the specific time material will be supplied and overtaxing of resources can still otherwise occur.

In still other implementations, the interaction among the functional components can be different to accommodate specific requirements. For example, in one alternative example, the allocation manager 320 is capable of communicating directly with the database 340. This allows the allocation manager 320 to directly and/or independently monitor resource usage and react more quickly to the dynamics at any given time. For example, the allocation manager 320 can monitor flag setting such that if more than a particular number of flags are set within a particular window of time, this may indicate a need for additional resources. In another example, the allocation manager 320 and the billing manager 350 may directly communicate, for example, to control utilization of resources by a content source 120 if they significantly exceed an estimate or are in arrears.

In yet other variants, the monitor/calculator 330 can provide actual usage feedback to the estimate handler, for example, to provide feedback to the content source 140 or for future needs estimation.

In still other variants, the monitor function of the monitor/calculator 330 can be separated such that some or all of the billing manager 350, estimate handler 310, allocation manager 320 and/or provider 200 perform monitoring and the calculator function receives the results of that monitoring from those entities.

In still other variants, the content source can contract based upon a combination of conventional parameters and compound parameters. For example, an agreement between the content source 140 and a provider 200 using a system 300 may specify a fixed rate for up to 1000 downloads per hour and, once that limit has been reached, surcharge billing based upon megabytes of storage required per download per amount of bandwidth required as a percent of total bandwidth available. It should be noted however, that such variants may suffer from more of the drawbacks found in existing systems than variants where estimates are based upon compound combinations of measurable parameters.

In further variants, the content source 140 is required to update their estimate with some specified “leadtime” to enable the system 300 to more accurately plan for peak needs. Those updates or “adjustment cycles” may coincide with one or more measurement or billing cycles or may be independent thereof.

It should be apparent that although various processes and implementations have been discussed, in many cases, some of those processes or their component parts can happen in different orders or concurrent with other steps. Similarly, various implementation differences can readily be employed, such as distributing databases or using multiple loosely or tightly coupled processors. Thus, while a number of embodiments have been shown and described, it should be understood that the above description is only representative of illustrative embodiments. For the convenience of the reader, the above description has focused on a representative sample of all possible embodiments, a sample that teaches the principles of the invention, further embodiments may also result from a different combination of described portions of different embodiments. The description has not attempted to exhaustively enumerate all possible variations. That alternate embodiments may not have been presented for a specific portion of the invention, may result from a different combination of described portions of different embodiments, or that further undesired alternate embodiments may be available for a portion, is not to be considered a disclaimer of those alternate embodiments. It will be appreciated that many of those undescribed embodiments are literally within the scope of the invention and others are equivalent.

What is claimed is:

1. A method of providing resources comprising:
receiving a value representing an estimate of a calculated expected resource usage under a billing plan within a cycle, the value being derived from at least two measurable resource parameters, the billing plan comprising a charge of a base amount when an actual calculated resource usage during the cycle does not exceed the calculated expected resource usage and a surcharge when the actual calculated resource usage during the cycle exceeds the calculated expected resource usage;
measuring, during a period, at least two parametric resource values representative of resource usage;
calculating a current actual resource usage value based upon a result of the measuring;
determining if the estimate has been exceeded within the cycle by comparing the current actual resource usage value with the value; and
billing according to the plan based upon a result of the determining.

2. The method according to claim 1, wherein the measuring comprises continuously measuring.

3. The method according to claim 1, wherein the measuring comprises measuring at regular intervals.

4. The method according to claim 1, wherein the measuring comprises measuring storage utilization.

5. The method according to claim 4, wherein the measuring comprises measuring processor utilization.

6. The method according to claim 4, wherein the measuring comprises measuring bandwidth utilization.

7. The method according to claim 1, wherein the calculating comprises:
dividing a first measured parametric value by a second measured parametric value.

8. The method according to claim 7, wherein one of the first or second measured parametric values comprises one of:
bandwidth, units of storage, hits, a number of files, pages, an amount of processor utilization.

9. The method according to claim 8, wherein the other of the first or second measured parametric values is different from the one of the first or second measured parametric values and comprises one of:
bandwidth, units of storage, hits, a number of files, pages, an amount of processor utilization.

10. The method according to claim 1, further comprising:
storing the current actual resource usage value.

11. The method according to claim 1, further comprising storing the value as the estimate.

12. The method according to claim 1, wherein the calculating comprises:
adding a new measured parameter amount to an accumulated measured parameter amount.

13. The method according to claim 1, further comprising:
prior to the billing, borrowing a next cycle estimate amount when a result of the comparing indicates that the estimate has been exceeded.

14. The method according to claim 1 wherein, when the comparing the current actual resource usage value with the value determines that the estimate has not been exceeded, the method further comprises:
adding an estimate surplus from the cycle to the estimate to obtain the value.

15. A method of allocating resources comprising:
receiving a value representing an estimate of a calculated expected resource usage under a billing plan within a cycle, the value being derived from at least two measurable resource parameters;
aggregating the value with a current actual resource usage for the cycle; and
adjusting a resource allocation based upon a comparing of a result of the aggregating and a current available resource amount.

16. The method according to claim 15, wherein the adjusting comprises:
adding additional resources.

17. The method according to claim 15, wherein the adjusting comprises:
shifting resources.

18. The method according to claim 15, further comprising:
bringing additional provider resources online.

19. The method according to claim 15 further comprising:
billing for a charge of a base amount when an actual calculated resource usage during the cycle does not exceed the calculated expected resource usage and adding a surcharge to the charge when the actual calculated resource usage during the cycle exceeds the calculated expected resource usage.

20. A method of billing for provision of resources comprising:
receiving a value representing an estimate of a calculated expected resource usage under a billing plan within a cycle, the value comprising a mathematical combination of at least two measurable resource parameters, the billing plan comprising a charge for a base amount when an actual calculated resource usage during the cycle does not exceed the calculated expected resource usage and a surcharge when the actual calculated resource usage during the cycle exceeds the calculated expected resource usage;
comparing the actual calculated resource usage with the value to determine if the estimate has been exceeded; and
if the estimate has been exceeded and a pre-determined condition is met, aggregating the charge for the base amount with a surcharge, otherwise, if the estimate has not been exceeded but the pre-determined condition is met, applying only the charge for the base amount.

21. The method according to claim 20, further comprising identifying whether a specified time period has elapsed.

22. The method according to claim 20, further comprising storing the value in a database.

23. The method according to claim 20, further comprising:
identifying the surcharge from one of a ramp, a step, an over carry or an u-limit carry plan.

24. A system comprising:
an estimate handler,
an allocation manager,
a monitor/calculator coupled for communication with at least the allocation manager and configured to monitor resource usage based upon communication between a provider and a user and calculate an actual usage value from parameters measured during the resource usage, and
a billing manager, the billing manager and allocation manager being communicatively connected to the estimate handler so that, as the monitor/calculator monitors the resource usage, the monitor/calculator will provide the actual usage value to the allocation manager for use in resource allocation and the billing manager for use in billing according to a billing plan, the billing plan including a surcharge to a source when a total actual usage value incorporating the actual usage value exceeds an estimated resource need value.

25. The system of claim 24 further comprising:
a database, coupled to the monitor/calculator and constructed to temporarily store information provided by the monitor/calculator.

26. The system of claim 25 wherein the database is also accessible to the billing manager.

27. The system of claim 25 wherein the database further comprises at least two fields, a first of the fields comprising an overage indicator flag and a second of the two fields comprising a current usage accumulation field.

28. The system of claim 24 wherein the billing plan comprises one of a ramp plan, a step plan, an over carry plan, or a u-limit carry plan.

29. A system comprising:
means for receiving a value representing an estimate of a calculated expected resource usage under a billing plan within a cycle, the value comprising at least two measurable resource parameters;
means for converting the measurable resource parameters to a calculated parametric value representative of a current actual resource usage, based upon a measuring within the cycle; and
means for comparing the calculated parametric value with the estimate and setting an overage indicator when the calculated parametric value exceeds the estimate.

30. The system according to claim 29, wherein the billing manager further comprises:
means for monitoring resource usage.

31. The system according to claim 29 further comprising:
means for matching available resources to a calculated expected resource need.

32. A system comprising:
a central processor unit configured to determine if an aggregate of a system actual resource usage and a value, calculated from at least two measurable resource parameters and representing an estimate of a calculated expected resource usage under a billing plan within a cycle, will exceed an available resource capacity; and
a database containing data, at least some of the data collectively representing the system actual resource usage, at a point in time.

33. A program, stored on a computer readable medium, comprising:
a module to calculate a usage value representing resource usage for an entity under a billing plan within a cycle, calculated from measurements of at least two measurable parameters; and
a module to bill for excess resource usage when an expected resource usage for the entity is less than the usage value for the entity within the cycle.

34. A computer readable medium having modules stored thereon, comprising:
a module that, when executed, will processes received estimates of expected resource usage derived from a combination of at least two measurable parameters;
a module that, when executed, will allocate resources based upon the received estimates and a current system resource state;
a module that, when executed, calculates a usage value from at least two measured parametric values; and
a module that, upon a completion of a billing cycle, bills an entity for a base charge when an actual calculated resource usage during the cycle does not exceed an expected resource usage and adds a surcharge when the actual calculated resource usage during the cycle exceeds the expected resource usage.

35. A programmed computer for managing resources, comprising:
storage and a processor, the storage having at least one program module which when executed by the processor performs the method of claim 1.
